(19) United States
(12) Patent Application Publication
(10) Pub. No.: US 2025/0228043 A1
(43) Pub. Date: Jul. 10, 2025

(54) TRANSFERRABLE POLYCHROMIC microLEDs

(71) Applicant: Lumileds LLC, San Jose, CA (US)

(72) Inventor: Brendan J. Moran, San Jose, CA (US)

(73) Assignee: Lumileds LLC, San Jose, CA (US)

(21) Appl. No.: 18/408,016

(22) Filed: Jan. 9, 2024

(51) Int. Cl. H01L 33/38; H01L 25/075; H01L 33/00; H01L 33/32

(52) U.S. Cl. CPC H10H 20/831; H10H 20/825; H01L 25/0753; H10H 20/0137; H10H 20/032

(57) ABSTRACT

Provided is an LED comprised of a single mesa epitaxial stack structure with a set of three p-n junctions and having four electrical contact terminals. A polychromatic, multi/full-color emitting, LED chip is assembled with a backplane and has four electrical contact terminals. The polychromatic LED is transferrable and able to be integrated each individually or as a mass array.

### TECHNICAL FIELD

Embodiments of the disclosure generally relate to light emitting diode (LED) devices and methods of manufacturing the same. More particularly, embodiments are directed to polychromatic (multi/full-color emitting) light emitting diode devices having four electrical contact terminals that are able to be transferred and integrated as each individual or as a mass array.

### BACKGROUND

A light emitting diode (LED) is a semiconductor light source that emits visible light when current flows through it. LEDs combine a P-type semiconductor with an N-type semiconductor. LEDs commonly use a III-group compound semiconductor. A III-group compound semiconductor provides stable operation at a higher temperature than devices that use other semiconductors. The III-group compound is typically formed on a substrate formed of sapphire or silicon carbide (SiC).

A polychromatic LED chip has four electrical contact terminals, for a set of three junctions, to drive it as a full-color light emitting device. When a polychromatic LED is assembled with a silicon-electronics-based driver circuit, commonly referred to as a “backplane”, a polychromatic LED chip requires a distinguished circuitry design.

Accordingly, there is a need for improved LED devices and fabricated chips that are electrically functional in an assembly, e.g., a direct-view display.

### SUMMARY

Embodiments of the disclosure are directed to LED devices and methods for manufacturing LED devices. In one or more embodiments, a light emitting diode (LED) device comprises an epitaxial stack comprising a first p-n junction, a second p-n junction, and a third p-n junction on a substrate; a first electrical contact terminal in contact with the epitaxial stack; a second electrical contact terminal in contact with the epitaxial stack; a third electrical contact terminal in contact with the epitaxial stack; and a fourth electrical contact terminal in contact with the epitaxial stack.

Additional embodiments of the disclosure are directed to LED direct-view display. In one or more embodiments, an LED direct-view display comprises: an LED device including epitaxial stack comprising a first p-n junction, a second p-n junction, and a third p-n junction on a substrate, a first electrical contact terminal in contact with the epitaxial stack, a second electrical contact terminal in contact with the epitaxial stack, a third electrical contact terminal in contact with the epitaxial stack, and a fourth electrical contact terminal in contact with the epitaxial stack; a backplane; and interconnects connecting the LED device to the backplane.

Further embodiments of the disclosure are directed to methods of manufacturing an LED device. In one or more embodiments, a method of manufacturing a light-emitting diode (LED) device comprises: epitaxially growing an epitaxial stack on a substrate, the epitaxial stack comprising a first p-n junction, a second p-n junction, and a third p-n junction; forming a first electrical contact terminal in contact with the epitaxial stack; forming a second electrical contact terminal in contact with the epitaxial stack; forming a third electrical contact terminal in contact with the epitaxial stack; and forming a fourth electrical contact terminal in contact with the epitaxial stack.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1 illustrates a cross-section schematic of an epitaxial stack according to one or more embodiments;

FIGS. 2-4 illustrate cross-section schematics of polychromatic chip types and backplane assembly;

FIGS. 5A-5D illustrate plan views of various flip chip types showing possible four-contact plans;

FIG. 6 illustrates a process flow diagram for a method of manufacturing an LED device according to one or more embodiments;

FIG. 7 illustrates an example of a general device in accordance with some embodiments;

FIG. 8 illustrates an example lighting system, according to some embodiments;

FIG. 9 illustrates an example hardware arrangement for implementing the above disclosed subject matter, according to some embodiments;

FIG. 10 shows a block diagram of an example of a system, according to some embodiments; and

FIG. 11 illustrates an example method of fabricating an illumination device, according to some embodiments.

To facilitate understanding, identical reference numerals have been used, where possible, to designate identical elements that are common to the figures. The figures are not drawn to scale. For example, the heights and widths of the mesas are not drawn to scale.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “substrate” as used herein according to one or more embodiments refers to a structure, intermediate or final, having a surface, or portion of a surface, upon which a process acts. In addition, reference to a substrate in some embodiments also refers to only a portion of the substrate, unless the context clearly indicates otherwise. Further, reference to depositing on a substrate according to some embodiments includes depositing on a bare substrate or on a substrate with one or more layers, films, features, or materials deposited or formed thereon.

In one or more embodiments, the “substrate” means any substrate or material surface formed on a substrate upon which film processing is performed during a fabrication process. In exemplary embodiments, a substrate surface on which processing is performed includes materials such as silicon, silicon oxide, silicon on insulator (SOI), strained silicon, amorphous silicon, doped silicon, carbon doped silicon oxides, germanium, gallium arsenide, glass, sapphire, and any other suitable materials such as metals, metal nitrides, III-nitrides (e.g., GaN, AlN, InN, and other alloys), metal alloys, and other conductive materials, depending on the application. Substrates include, without limitation, light emitting diode (LED) devices. Substrates in some embodiments are exposed to a pretreatment process to polish, etch, reduce, oxidize, hydroxylate, anneal, UV cure, e-beam cure and/or bake the substrate surface. In addition to film processing directly on the surface of the substrate itself, in some embodiments, any of the film processing steps disclosed is also performed on an underlayer formed on the substrate, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

The term “wafer” and “substrate” will be used interchangeably in the instant disclosure. Thus, as used herein, a wafer serves as the substrate for the formation of the LED devices described herein.

Examples of different light illumination systems and/or light emitting diode (LED) implementations will be described more fully hereinafter with reference to the accompanying drawings. These examples are not mutually exclusive, and features found in one example may be combined with features found in one or more other examples to achieve additional implementations. Accordingly, it will be understood that the examples shown in the accompanying drawings are provided for illustrative purposes only and they are not intended to limit the disclosure in any way. Like numbers refer to like elements throughout.

Semiconductor light emitting devices or optical power emitting devices, such as devices that emit ultraviolet (UV) or infrared (IR) optical power, are among the most efficient light sources currently available. These devices may include light emitting diodes, resonant cavity light emitting diodes, vertical cavity laser diodes, edge emitting lasers, or the like (hereinafter referred to as “LEDs”). Due to their compact size and lower power requirements, for example, LEDs may be attractive candidates for many different applications. For example, they may be used as light sources (e.g., flashlights and camera flashes) for hand-held battery-powered devices, such as cameras and cell phones. They may also be used, for example, for automotive lighting, heads up display (HUD) lighting, horticultural lighting, street lighting, torch for video, general illumination (e.g., home, shop, office and studio lighting, theater/stage lighting and architectural lighting), augmented reality (AR) lighting, virtual reality (VR) lighting, as back lights for displays, and IR spectroscopy. A single LED may provide light that is less bright than an incandescent light source, and, therefore, multi-junction devices or arrays of LEDs (such as monolithic LED arrays, micro-LED arrays, etc.) may be used for applications where more brightness is desired or required.

The present disclosure generally relates to the manufacture of LEDs and flip chips for direct-view displays. As used herein, the term “polychromatic” refers to light that exhibits more than one color, containing radiation of more than one wavelength. The polychromatic combination of blue-, green- and red-wavelength light emitted from the LED device of one or more embodiments may appear white or near-white in color. In one or more embodiments, the intensity of blue-, green- and red-wavelength light emitted from the device may be balanced in any suitable manner known to the skilled artisan, including, but not limited to manipulation of the number and/or thickness of quantum wells of each type and the use of filters or reflective layers.

Embodiments described herein describe LED devices and methods for forming LED devices. In particular, the present disclosure describes LED devices and methods to produce LED devices which are comprised of a single mesa structure with a set of three junctions and having four electrical contacts. In one or more embodiments, a polychromatic, multi/full-color emitting, LED chip is assembled onto a backplane and has four electrical contact terminals. The polychromatic LED of one or more embodiments is transferrable to this backplane or any other suitable receiver and able to be integrated each individually or as a mass array. In one or more embodiments, a polychromatic LED flip chip is connected to a backplane using four electrically independent contacts. In other embodiments, a polychromatic chip has four independent electrical contacts on one side of the chip. In further embodiments, a polychromatic chip has three electrically independent contacts on one side of the chip and a fourth electrically independent contact on an opposing side of the chip. In one or more embodiments, a polychromatic chip has three electrically independent contacts on one side of the chip and a fourth electrically independent contact on an adjacent side of the chip. In some embodiments, the polychromatic LED chip has an epitaxial substrate attached. In other embodiments, the epitaxial substrate has been removed during the chip fabrication process. In one or more embodiments, the chip-attached backplane is either active electrical circuitry or passive interposer.

As used herein, the term “p-n junction” refers to a boundary between two semiconductor layers of opposite conductivity types p-type and n-type. The “p” side contains an excess of holes, while the “n” side contains an excess of electrons. The excesses of holes and electrons may be obtained by intentional doping with acceptor or donor impurities, respectively, and/or may result from the presence of native crystal defects. Said boundary is not necessarily abrupt, planar, or smooth. Said boundary may include of gradients in impurity concentration and/or layers of intrinsic (neutral) conductivity type between the p-type and n-type layers. Said boundary may feature protrusions of p-type semiconductor into the n-type semiconductor, or vice-versa.

The embodiments of the disclosure are described by way of the Figures, which illustrate devices and processes for forming devices in accordance with one or more embodiments of the disclosure. The processes shown are merely illustrative possible uses for the disclosed processes, and the skilled artisan will recognize that the disclosed processes are not limited to the illustrated applications.

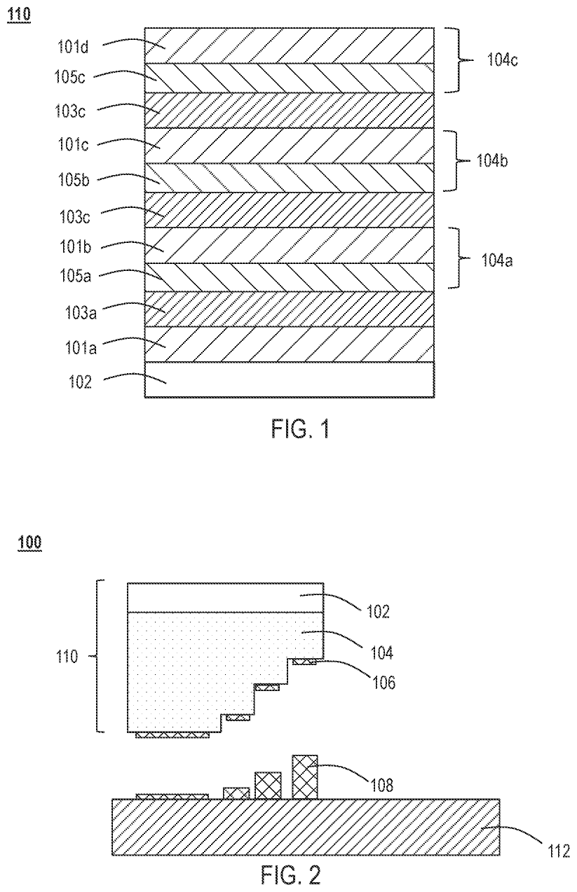

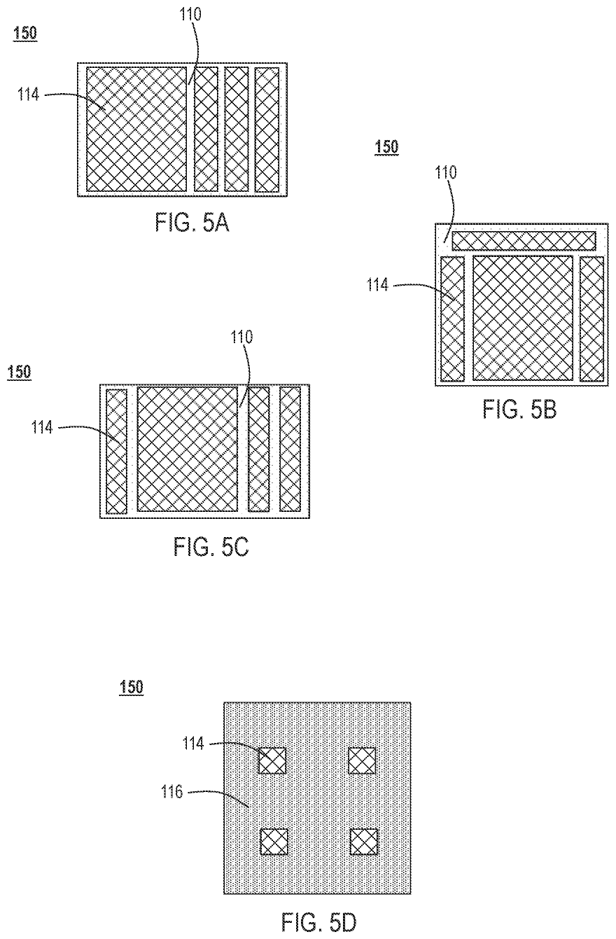

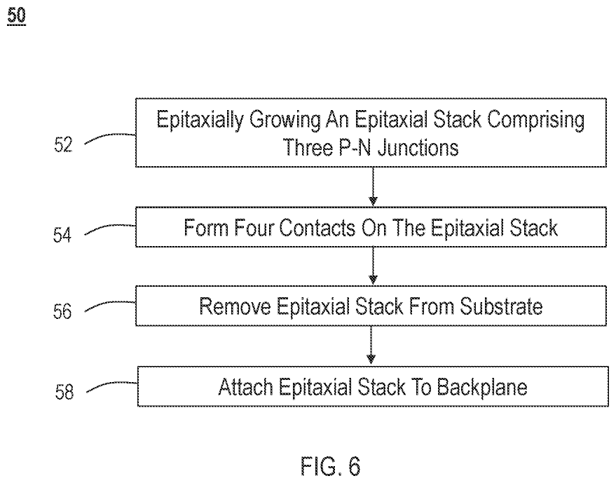

One or more embodiments of the disclosure are described with reference to the Figures. FIG. 1 illustrates a cross-sectional schematic of an epitaxial stack 105 according to one or more embodiments. FIGS. 2-4 illustrate cross-sectional schematics of an LED device 100, according to one or more embodiments. An additional aspect of the disclosure pertains to flip chip types, as illustrated in FIGS. 5A-5D. FIG. 6 illustrates a process flow diagram for a method 50 of manufacturing an LED device according to one or more embodiments.

With reference to FIG. 6, in one or more embodiments, the method 50 begins at operation 52 by epitaxially growing an epitaxial stack comprising three p-n junctions on a substrate. At operation 54 four contacts are formed on the epitaxial stack. At operation 56, the epitaxial stack is removed from the substrate. At operation 58, the epitaxial stack is attached to a backplane.

Referring to FIG. 1, an example LED epitaxial stack 105 is manufactured by forming a plurality of III-nitride layers on a substrate 102 including three p-n junctions. The p-n junctions may include a first p-n junction 104a, a second p-n junction 104b, and a third p-n junction 104c. It will be appreciated by one of skill in the art that the stacking of layers of the epitaxial stack 105 in FIG. 1 is for illustrative purposes only. The epitaxial stack 105 may have any combination of p-type layers, n-type layers, and light-emitting active regions.

In one or more embodiments, the epitaxial stack includes three light-emitting active regions. The light-emitting active regions may include a first light-emitting active region 103a, a second light-emitting active region 103b, and a third light-emitting active region 103c. Any order of stacking the different active regions is within the scope of the disclosure.

In one or more embodiments, one or more of the first active region, the second region, and the third active region emits blue light. In other embodiments, one or more of the first active region, the second region, and the third active region emits red light. In still further embodiments, one or more of the first active region, the second region, and the third active region emits green light.

According to certain specific embodiments, the LED epitaxial stack 105 comprises a first n-type layer 101a formed on the substrate 102, a first light-emitting active region 103a grown on the first n-type layer 101a, a p-type layer 105a formed on the first light-emitting active region 103b to form the first p-n junction 104a. A second p-n junction 104b is formed on the first p-n junction 104a. The second p-n junction 104b includes a second n-type layer 101b formed on the first p-type layer 105a, a second light-emitting active region 103b grown on the second n-type layer 101b, and a second p-type layer 105b formed on the second light-emitting active region 103b. A third p-n junction 104c is formed on the second p-n junction 104b. The third p-n junction 104c includes a third n-type layer 101c formed on the second p-type layer 105b, a third light-emitting active region 103c grown on the third n-type layer 101c, a third p-type layer 105c formed on the third light-emitting active region 103c, and a fourth n-type layer 101d on the third p-type layer 105c.

In one or more embodiments, the first light-emitting active region 103a, the second light emitting active region 103b, and the third light emitting active region 103c are selected to be either a blue light emitting active region, a red light emitting active region, or a green light emitting active region. In one or more unillustrated embodiments, there may be at least one tunnel junction on the light-emitting active regions 103a, 103b, 103c. A tunnel junction is a structure that allows electrons to tunnel from the valence band of a p-type layer to the conduction band of an n-type layer in reverse bias. The location where a p-type layer and an n-type layer abut each other is called a p-n junction. When an electron tunnels, a hole is left behind in the p-type layer, such that carriers are generated in both regions. Accordingly, in an electronic device like a diode, where only a small leakage current flows in reverse bias, a large current can be carried in reverse bias across a tunnel junction. A tunnel junction comprises a particular alignment of the conduction and valence bands at the p-n tunnel junction. This can be achieved by using very high doping (e.g., in the p++/n++ junction). In addition, III-nitride materials have an inherent polarization that creates an electric field at heterointerfaces between different alloy compositions. In some circumstances, this polarization field can also be utilized to achieve band alignment for tunneling.

In one or more embodiments, a nucleation layer (not illustrated) and dislocation density control layers (not illustrated) may be grown on a suitable substrate 102, such as patterned or non-patterned sapphire. In one or more embodiments, the nucleation layer comprises a III-nitride material. In specific embodiments, the nucleation layer comprises gallium nitride (GaN) or aluminum nitride (AlN).

In one or more embodiments, the first n-type layer 101a is grown on the substrate 102, the nucleation layer, and/or the dislocation density control layers. In one or more embodiments, the first n-type layer 101a is formed on the substrate 102. The substrate 102 may be any substrate known to one of skill in the art which is configured for use in the formation of LED devices. In one or more embodiments, the substrate 102 comprises one or more of sapphire, silicon carbide, silicon (Si), quartz, magnesium oxide (MgO), zinc oxide (ZnO), spinel, and the like. In one or more embodiments, the substrate 102 is a transparent substrate. In specific embodiments, the substrate 102 comprises sapphire. In one or more embodiments, the substrate 102 is not patterned prior to formation of the LEDs. Thus, in some embodiments, the substrate is 102 not patterned and can be considered to be flat or substantially flat. In other embodiments, the substrate 102 is a patterned substrate.

In one or more embodiments, the n-type layer 101, may comprise any Group III-V semiconductors material, including binary, ternary, and quaternary alloys of gallium (Ga), aluminum (Al), indium (In), and nitrogen (N), also referred to as III-nitride materials. Thus, in some embodiments, the n-type layer 101, comprises one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like. In a specific embodiment, the n-type layer 101, the second n-type layer 101b, the third n-type layer 101c, and the fourth n-type layer 101d comprise gallium nitride (GaN). In one or more embodiments, the n-type layer 101 is doped with an n-type dopant, such as silicon (Si) or germanium (Ge). In one or more embodiments, the dopant concentration is in a range of from 1 e17 to 2e19 cm3. In one or more embodiments, the n-type layer 101 may have a thickness in the range of from 1 μm to 3 μm to ensure a wide process margin for a subsequent etching step used to contact this layer.

In one or more embodiments, the layers of III-nitride material may be deposited by one or more of sputter deposition, atomic layer deposition (ALD), metalorganic chemical vapor deposition (MOCVD), physical vapor deposition (PVD), plasma enhanced atomic layer deposition (PEALD), and plasma enhanced chemical vapor deposition (PECVD).

“Sputter deposition” as used herein refers to a physical vapor deposition (PVD) method of thin film deposition by sputtering. In sputter deposition, a material, e.g., a III-nitride, is ejected from a target that is a source onto a substrate. The technique is based on ion bombardment of a source material, the target. Ion bombardment results in a vapor due to a purely physical process, i.e., the sputtering of the target material.

As used according to some embodiments herein, “atomic layer deposition” (ALD) or “cyclical deposition” refers to a vapor phase technique used to deposit thin films on a substrate surface. The process of ALD involves the surface of a substrate, or a portion of substrate, being exposed to alternating precursors, i.e., two or more reactive compounds, to deposit a layer of material on the substrate surface. When the substrate is exposed to the alternating precursors, the precursors are introduced sequentially or simultaneously. The precursors are introduced into a reaction zone of a processing chamber, and the substrate, or portion of the substrate, is exposed separately to the precursors.

As used herein according to some embodiments, “chemical vapor deposition” refers to a process in which films of materials are deposited from the vapor phase by decomposition of chemicals on a substrate surface. In CVD, a substrate surface is exposed to precursors s simultaneously or substantially simultaneously. A particular subset of CVD processes commonly used in LED manufacturing use metalorganic precursor chemical and are referred to as MOCVD or metalorganic vapor phase epitaxy (MOVPE). As used herein, “substantially simultaneously” refers to either co-flow or where there is overlap for a majority of exposures of the precursors.

As used herein according to some embodiments, “plasma enhanced atomic layer deposition (PEALD)” refers to a technique for depositing thin films on a substrate. In some examples of PEALD processes relative to thermal ALD processes, a material may be formed from the same chemical precursors, but at a higher deposition rate and a lower temperature. In a PEALD process, in general, a reactant gas and a reactant plasma are sequentially introduced into a process chamber having a substrate in the chamber. The first reactant gas is pulsed in the process chamber and is adsorbed onto the substrate surface. Thereafter, the reactant plasma is pulsed into the process chamber and reacts with the first reactant gas to form a deposition material, e.g., a thin film on a substrate. Similar to a thermal ALD process, a purge step may be conducted between the deliveries of each of the reactants.

As used herein according to one or more embodiments, “plasma enhanced chemical vapor deposition (PECVD)” refers to a technique for depositing thin films on a substrate. In a PECVD process, a source material, which is in gas or liquid phase, such as a gas-phase III-nitride material or a vapor of a liquid-phase III-nitride material that have been entrained in a carrier gas, is introduced into a PECVD chamber. A plasma-initiated gas is also introduced into the chamber. The creation of plasma in the chamber creates excited radicals. The excited radicals are chemically bound to the surface of a substrate positioned in the chamber, forming the desired film thereon.

In one or more embodiments, μLED array 100 is manufactured by placing the substrate 102 in a metalorganic vapor-phase epitaxy (MOVPE) reactor so that the μLED array layers are grown epitaxially.

In one or more embodiments, after the growth of the first n-type layer 101a, a first light-emitting active region 103a is grown. The first light-emitting active region 103a consists of multiple quantum wells and may include electron blocking layer(s) grown after the quantum wells and strain-control layers grown before the quantum wells. The process of growing the strain-control layers may generate V-pit defects before the growth of the first quantum well. The number of quantum wells typically used for blue LEDs ranges from 3 to 15, the typical barrier thickness ranges from 5 nm to 25 nm, the well thickness ranges from 1 nm to 5 nm, and the well indium concentration ranges from 15% indium to 25% indium. The number of quantum wells typically used for green LEDs ranges from 4 to 12, the typical barrier thickness ranges from 5 nm to 25 nm, the well thickness ranges from 1 nm to 5 nm, and the well indium concentration ranges from 15% indium to 25% indium.

In one or more embodiments, after the light-emitting active region 103a is grown, a p-type layer 105a is grown on the first light-emitting active region 103a.

In one or more embodiments, p-type layer 105 comprises any Group III-V semiconductor material, including binary, ternary, and quaternary alloys of gallium (Ga), aluminum (Al), indium (In), and nitrogen (N), also referred to as III-nitride materials. Thus, in some embodiments, the p-type layer 105a, 105b, 105c comprises one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like. In one or more embodiments, magnesium (Mg) is the acceptor dopant for the p-type layer 105a, 105b, 105c.

In some embodiments, the p-type layer 105 comprises a sequence of doped p-type layers. In one or more embodiments, the p-type layer 105 comprises a gallium nitride (GaN) layer. The p-type layer 105 may be doped with any suitable p-type dopant known to the skilled artisan. In one or more embodiments, p-type layer 105 may be doped with magnesium (Mg). In one or more embodiments, the p-type layer 105 comprises a first magnesium doped p-type aluminum gallium nitride layer, a magnesium doped p-type gallium nitride layer, and a second magnesium doped p-type aluminum gallium nitride layer.

FIG. 2 illustrates a cross-section schematic of an LED device 100 after operation 54 (FIG. 6) when four electrical contact terminals contacts 106 have been formed on the epitaxial stack 110. The four electrical contact terminals may include a first electrical contact terminal, a second electrical contact terminal, a third electrical contact terminal, and a fourth electrical contact terminal. In one or more embodiments, four contact terminals 106 are formed on the epitaxial stack 110 side of the device 100. In one or more embodiments, four contact terminals 106 are formed on the same side of the epitaxial stack 110. In one or more embodiments, the first electrical contact terminal, the second electrical contact terminal, the third electrical contact terminal, and the fourth electrical contact terminal are on the same side of the device 100. In one or more embodiments, the first electrical contact terminal, the second electrical contact terminal, and the third electrical contact terminal are on the same side of the device, and the fourth electrical contact terminal is on an opposing side of the epitaxial stack. In other embodiments, the first electrical contact terminal, the second electrical contact terminal, and the third electrical contact terminal are on the same side of the device, and the fourth electrical contact terminal is on an adjacent side of the epitaxial stack.

In one or more embodiments, the LED device 100 forms a part of a direct-view display. A direct-view display uses LEDs to produce the red, blue, and green colors. In a direct-view display, light-emitting diodes are mounted directly on a printed circuit board (PCB).

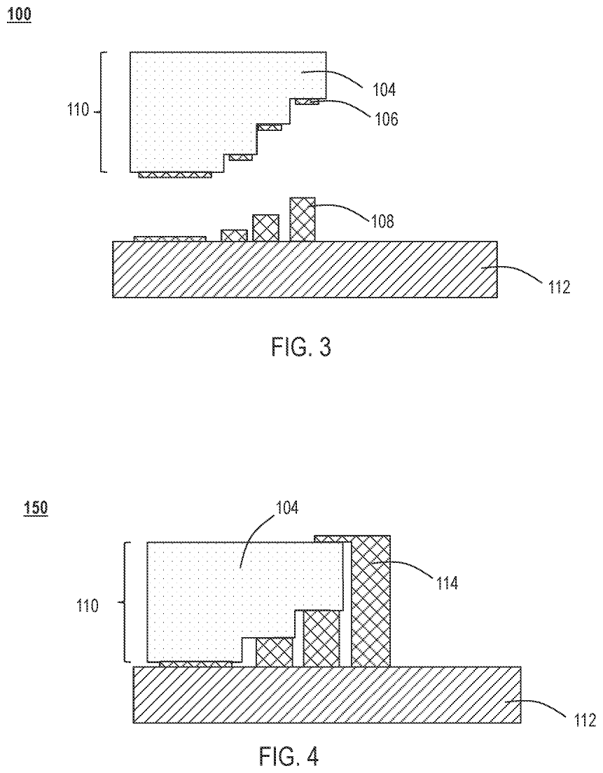

FIG. 3 illustrates a cross-section schematic of an LED device 100 after operation 56 (FIG. 6), where the substrate 102 has been separated from the epitaxial stack 110 and the four contacts 106. In one or more embodiments, a backplane 112 contacting backplane contacts 108 may be aligned with the epitaxial stack 110.

FIG. 4 illustrates a cross-section schematic of a hardware arrangement after operation 56 where the contacts 106 of the epitaxial stack 110 have been connected to the contacts 110 of the backplane 112 to form the interconnects 114.

In particular, the hardware arrangement 150 may include the LED device 100 that contains the LED epitaxial stack 110 of one or more embodiments and a backplane 112, such as a CMOS backplane. In one or more embodiments, the backplane 112 may include one or more of active electrical circuitry or passive interposer. The LED die device 100 may be coupled to the CMOS backplane 112 by one or more interconnects 114, where the interconnects 114 may provide for transmission of signals between the LED device 100 and the CMOS backplane 112. The interconnects 114 may comprise one or more solder bump joints, one or more copper pillar bump joints, other types of interconnects known in the art, or some combination thereof.

The LED device 100 may also include circuitry to implement the LED epitaxial stack described above. The LED device 100 may include a shared active layer and a shared substrate for an LED array, and thereby the LED array may be a monolithic LED array. Each LED device 100 of the LED array may include an individual segmented active layer and/or substrate. In some embodiments, the LED device 100 may further include switches and current sources to drive the device. In other embodiments, the switches and the current sources may be included in the CMOS backplane 112. The LEDs may be micro-LEDs or LEDs larger than micro-LEDs.

The CMOS backplane 112 may include circuitry to implement the control module. The CMOS backplane 112 may utilize the interconnects 114 to provide the LED device with the driving signals and the signals for the intensity for causing the LED device to produce light in accordance with the signals and the intensity.

The hardware arrangement 150 may further include a printed circuit board (PCB) (not illustrated) located on a bottom surface of the backplane 112. The PCB may include circuitry to implement various functionality described herein. The PCB may be coupled to the CMOS backplane 112. For example, the PCB may be coupled to the CMOS backplane 112 via one or more wire bonds (not illustrated). The PCB and the CMOS backplane 112 may exchange image data, power, and/or feedback via the coupling, among other signals.

The LEDs and circuitry supporting the LED array can be packaged and include a submount or printed circuit board (PCB) for powering and controlling light production by the LEDs. The PCB supporting the LED array may include electrical vias, heat sinks, ground planes, electrical traces, and flip chip or other mounting systems. The submount or PCB may be formed of any suitable material, such as ceramic, silicon, aluminum, etc. If the submount material is conductive, an insulating layer may be formed over the substrate material, and a metal electrode pattern formed over the insulating layer for contact with the micro-LED array. The submount can act as a mechanical support, providing an electrical interface between electrodes on the LED array and a power supply, and also provide heat sink functionality.

FIGS. 5A to 5D illustrate plan views of various possible flip chip types showing possible configurations/layouts. FIGS. 5A to 5D represent what connecting interface of a chip might be the above-mentioned CMOS or driving circuit board. They replace the traditional anode and cathode terminals for a typical LED since there are terminals in this polychromatic device. FIGS. 5A to 5D illustrate several ways that one may design the contacts, but it is noted that the configurations/layouts are not meant to be limiting. One of skill in the art recognizes that other configurations/layouts are possible.

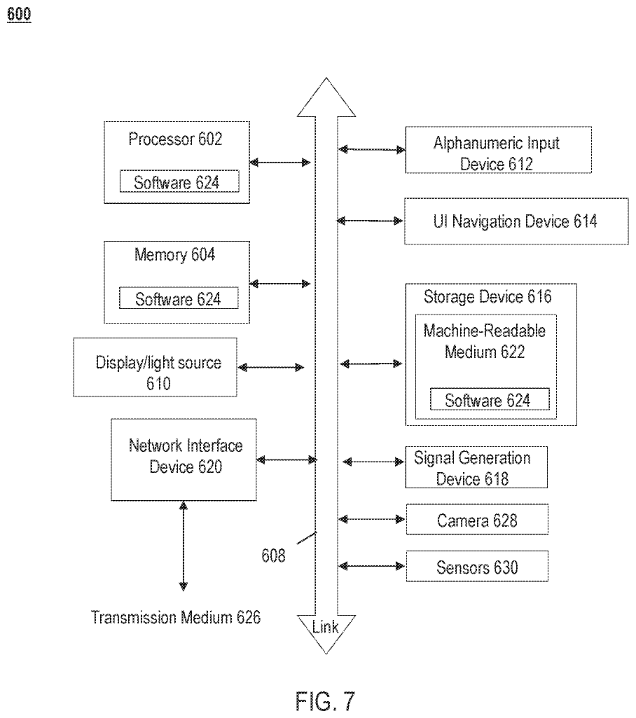

FIG. 7 illustrates an example of a general device in accordance with some embodiments. The device 600 may be a mobile device such as a laptop computer (PC), a tablet PC, a smart phone, or an augmented reality (AR)/virtual reality (VR), or an automotive device, for example. Various elements may be provided on the backplane indicated above, while other elements may be local or remote. Examples, as described herein, may include, or may operate on, logic or a number of components, modules, or mechanisms.

Modules and components are tangible entities (e.g., hardware) capable of performing specified operations and may be configured or arranged in a certain manner. In an example, circuits may be arranged (e.g., internally or with respect to external entities such as other circuits) in a specified manner as a module. In an example, the whole or part of one or more computer systems (e.g., a standalone, client or server computer system) or one or more hardware processors may be configured by firmware or software (e.g., instructions, an application portion, or an application) as a module that operates to perform specified operations. In an example, the software may reside on a machine readable medium. In an example, the software, when executed by the underlying hardware of the module, causes the hardware to perform the specified operations.

Accordingly, the term “module” (and “component”) is understood to encompass a tangible entity, be that an entity that is physically constructed, specifically configured (e.g., hardwired), or temporarily (e.g., transitorily) configured (e.g., programmed) to operate in a specified manner or to perform part or all of any operation described herein. Considering examples in which modules are temporarily configured, each of the modules need not be instantiated at any one moment in time. For example, where the modules comprise a general-purpose hardware processor configured using software, the general-purpose hardware processor may be configured as respective different modules at different times. Software may accordingly configure a hardware processor, for example, to constitute a particular module at one instance of time and to constitute a different module at a different instance of time.

The electronic device 600 may include a hardware processor (or equivalently processing circuitry) 602 (e.g., a central processing unit (CPU), a GPU, a hardware processor core, or any combination thereof), a memory 604 (which may include main and static memory), some or all of which may communicate with each other via an interlink (e.g., bus) 608. The memory 604 may contain any or all removable storage and non-removable storage, volatile memory, or non-volatile memory. The electronic device 600 may further include a display/light source 610 such as the LEDs described above, or a video display, an alphanumeric input device 612 (e.g., a keyboard), and a user interface (UI) navigation device 614 (e.g., a mouse). In an example, the display/light source 610, input device 612 and UI navigation device 614 may be a touch screen display. The electronic device 600 may additionally include a storage device (e.g., drive unit) 616, a signal generation device 618 (e.g., a speaker), a network interface device 620, one or more cameras 628, and one or more sensors 630, such as a global positioning system (GPS) sensor, compass, accelerometer, or other sensor such as those described herein. The electronic device 600 may further include an output controller, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

The storage device 616 may include a non-transitory machine readable medium 622 (hereinafter simply referred to as machine readable medium) on which is stored one or more sets of data structures or instructions 624 (e.g., software) embodying or utilized by any one or more of the techniques or functions described herein. The instructions 624 may also reside, completely or at least partially, within the memory 604 and/or within the hardware processor 602 during execution thereof by the electronic device 600. While the machine readable medium 622 is illustrated as a single medium, the term “machine readable medium” may include a single medium or multiple media (e.g., a centralized or distributed database, and/or associated caches and servers) configured to store the one or more instructions 624.

The term “machine readable medium” may include any medium that is capable of storing, encoding, or carrying instructions for execution by the electronic device 600 and that cause the electronic device 600 to perform any one or more of the techniques of the present disclosure, or that is capable of storing, encoding, or carrying data structures used by or associated with such instructions. Non-limiting machine-readable medium examples may include solid-state memories, and optical and magnetic media. Specific examples of machine-readable media may include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; Random Access Memory (RAM); and CD-ROM and DVD-ROM disks.

The instructions 624 may further be transmitted or received over a communications network using a transmission medium 626 via the network interface device 620 utilizing any one of a number of wireless local area network (WLAN) transfer protocols or a SPI or CAN bus. Example communication networks may include a local area network (LAN), a wide area network (WAN), a packet data network (e.g., the Internet), mobile telephone networks (e.g., cellular networks), Plain Old Telephone (POTS) networks, and wireless data networks. Communications over the networks may include one or more different protocols, such as Institute of Electrical and Electronics Engineers (IEEE) 802.11 family of standards known as Wi-Fi, IEEE 802.16 family of standards known as WiMax, IEEE 802.16.4 family of standards, a Long Term Evolution (LTE) family of standards, a Universal Mobile Telecommunications System (UMTS) family of standards, peer-to-peer (P2P) networks, a next generation (NG)/6th generation (6G) standards among others. In an example, the network interface device 620 may include one or more physical jacks (e.g., Ethernet, coaxial, or phone jacks) or one or more antennas to connect to the transmission medium 626.

Note that the term “circuitry” as used herein refers to, is part of, or includes hardware components such as an electronic circuit, a logic circuit, a processor (shared, dedicated, or group) and/or memory (shared, dedicated, or group), an Application Specific Integrated Circuit (ASIC), a field-programmable device (FPD) (e.g., a field-programmable gate array (FPGA), a programmable logic device (PLD), a complex PLD (CPLD), a high-capacity PLD (HCPLD), a structured ASIC, or a programmable SoC), digital signal processors (DSPs), etc., that are configured to provide the described functionality. In some embodiments, the circuitry may execute one or more software or firmware programs to provide at least some of the described functionality. The term “circuitry” may also refer to a combination of one or more hardware elements (or a combination of circuits used in an electrical or electronic system) with the program code used to carry out the functionality of that program code. In these embodiments, the combination of hardware elements and program code may be referred to as a particular type of circuitry.

The term “processor circuitry” or “processor” as used herein thus refers to, is part of, or includes circuitry capable of sequentially and automatically carrying out a sequence of arithmetic or logical operations, or recording, storing, and/or transferring digital data. The term “processor circuitry” or “processor” may refer to one or more application processors, one or more baseband processors, a physical central processing unit (CPU), a single- or multi-core processor, and/or any other device capable of executing or otherwise operating computer-executable instructions, such as program code, software modules, and/or functional processes.

The camera 628 may sense light at least the wavelength or wavelengths emitted by the LEDs. The camera 628 may include optics (e.g., at least one camera lens) that are able to collect reflected light of illumination that is reflected from and/or emitted by an illuminated region. The camera lens may direct the reflected light onto a multi-pixel sensor (also referred to as a light sensor) to form an image of on the multi-pixel sensor.

The processor 602 may control and drive the LEDs via one or more drivers. For example, the processor 602 may optionally control one or more LEDs in LED arrays independent of another one or more LEDs in the LED arrays, so as to illuminate an area in a specified manner.

In addition, the sensors 630 may be incorporated in the camera 628 and/or the light source 610. The sensors 630 may sense visible and/or infrared light and may further sense the ambient light and/or variations/flicker in the ambient light in addition to reception of the reflected light from the LEDs. The sensors may have one or more segments (that are able to sense the same wavelength/range of wavelengths or different wavelength/range of wavelengths), similar to the LED arrays.

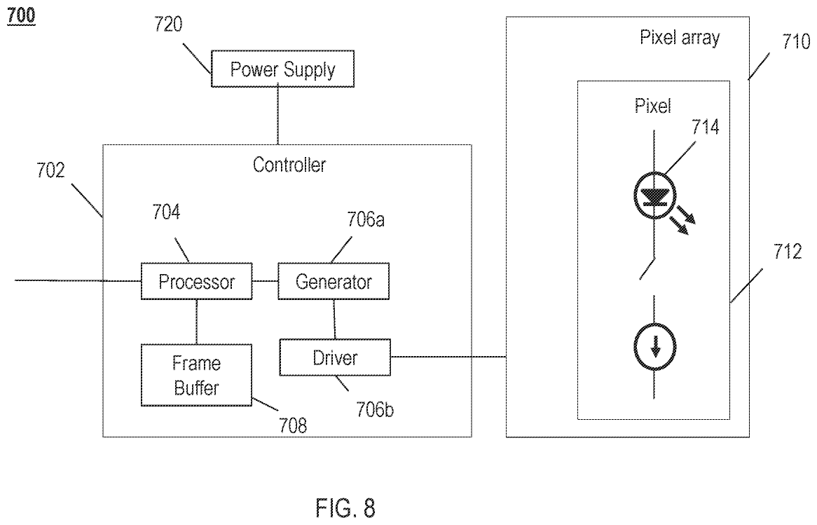

FIG. 8 illustrates an example lighting system, according to some embodiments. As above, some of the elements shown in the lighting system 700 may not be present, while other additional elements may be disposed in the lighting system 700. The lighting system 700 may include a controller 702 that controls illumination using a pixel array 710 that contains multiple individual pixels 712.

In some embodiments, some or all of the components described as the controller 702 may be disposed on a backplane such as, for example, a complementary metal oxide semiconductor (CMOS) backplane. The controller 702 may be coupled to or include one or more processors 704. The processor 704 may receive image data (in frames) via an interface and may process the image data to control a generator 706a, for example, controlling analog signals or PWM duty cycles and/or turn-on times for causing the lighting system 700 to produce the images indicated by the image data.

The controller 702 may further include a frame buffer 708. The frame buffer 708 may store one or more images prior to the one or more processors 704 and store the indications for implementation by the one or more processors 704.

The generator 706a may be controlled by the processor 704 and may produce driving signals in accordance with the indications. The generator 706a may be connected to a driver 706b to drive the pixel array 710 so that the pixels 712 provide desired intensities of light.

Each pixel 712 may include one or more LEDs 714. The LEDs 714 may be different colors and may be controlled individually or in groups. As shown, the pixel 712 may include, for each pixel 712 or LED 714, a PWM switch, and a current source. The pixel 712 may be driven by the driver 706b. The signal from the generator 706a may cause the switch to open and close in accordance with the value of the signal. The signal corresponding to the intensities of light may cause the current source to produce a current flow to cause the pixels 712 to produce the corresponding intensities of light.

The lighting system 700 may further include a power supply 720. In some embodiments, the power supply 720 may be a battery that produces power for the controller 702.

While only certain features of the system and method have been illustrated and described herein, many modifications and changes will occur to those skilled in the art. It is, therefore, to be understood that the appended claims are intended to cover all such modifications and changes. Method operations may be performed substantially simultaneously or in a different order.

### Embodiments

Various embodiments are listed below. It will be understood that the embodiments listed below may be combined with all aspects and other embodiments in accordance with the scope of the invention.

Embodiment (a). A light-emitting diode (LED) comprising: an epitaxial stack comprising a first p-n junction, a second p-n junction, and a third p-n junction on a substrate; a first electrical contact terminal in contact with the epitaxial stack; a second electrical contact terminal in contact with the epitaxial stack; a third electrical contact terminal in contact with the epitaxial stack; and a fourth electrical contact terminal in contact with the epitaxial stack.

Embodiment (b). The LED device of embodiment (a), wherein the device is a polychromatic LED chip.

Embodiment (c). The LED device of embodiment (b) to embodiment (c), wherein the first electrical contact terminal, the second electrical contact terminal, the third electrical contact terminal, and the fourth electrical contact terminal are on the same side of the device.

Embodiment (d). The LED device of embodiment (a) to embodiment (d), wherein the first electrical contact terminal, the second electrical contact terminal, and the third electrical contact terminal are on the same side of the device, and the fourth electrical contact terminal is on an opposing side of the epitaxial stack.

Embodiment (e). The LED device of embodiment (a) to embodiment (d), wherein the first electrical contact terminal, the second electrical contact terminal, and the third electrical contact terminal are on the same side of the device, and the fourth electrical contact terminal is on an adjacent side of the epitaxial stack.

Embodiment (f). The LED device of embodiment (a) to embodiment (e), wherein the epitaxial stack comprises an n-type layer, a p-type layer, and an active region.

Embodiment (g). The LED device of embodiment (a) to embodiment (f), wherein the epitaxial stack comprises a first active region, a second active region, and a third active region.

Embodiment (h). The LED device of embodiment (a) to embodiment (g), wherein one or more of the first active region, the second region, and the third active region emits blue light.

Embodiment (i). The LED device of embodiment (a) to embodiment (h), wherein one or more of the first active region, the second region, and the third active region emits red light.

Embodiment (j). The LED device of embodiment (a) to embodiment (i), wherein one or more of the first active region, the second region, and the third active region emits green light.

Embodiment (k). The LED device of embodiment (a) to embodiment (j), wherein one or more of the n-type layer, the active region, and the p-type layer independently comprises one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like.

Embodiment (l). The LED device of embodiment (a) to embodiment (k), wherein one or more of the n-type layer, the active region, and the p-type layer independently comprises gallium nitride (GaN).

Embodiment (m). The LED device of embodiment (a) to embodiment (l), wherein the device forms a part of a direct-view display.

Embodiment (n). The LED device of embodiment (a) to embodiment (m), wherein the device is a micro-LED.

Embodiment (o). An LED direct-view display comprising: an LED device including epitaxial stack comprising a first p-n junction, a second p-n junction, and a third p-n junction on a substrate, a first electrical contact terminal in contact with the epitaxial stack, a second electrical contact terminal in contact with the epitaxial stack, a third electrical contact terminal in contact with the epitaxial stack, and a fourth electrical contact terminal in contact with the epitaxial stack; a backplane; and interconnects connecting the LED device to the backplane.

Embodiment (p). The LED direct-view display of embodiment (o), wherein the backplane comprises one or more of active electrical circuitry or passive interposer.

Embodiment (q). A method of manufacturing a light-emitting diode (LED) device, the method comprising: epitaxially growing an epitaxial stack on a substrate, the epitaxial stack comprising a first p-n junction, a second p-n junction, and a third p-n junction; forming a first electrical contact terminal in contact with the epitaxial stack; forming a second electrical contact terminal in contact with the epitaxial stack; forming a third electrical contact terminal in contact with the epitaxial stack; and forming a fourth electrical contact terminal in contact with the epitaxial stack.

Embodiment (r). The method of embodiment (q), further comprising removing the epitaxial stack from the substrate.

Embodiment(s). The method of embodiment (q) and embodiment (r), further comprising attaching the epitaxial stack and the first electrical contact terminal, the second electrical contact terminal, the third electrical contact terminal and the fourth electrical contact terminal to a backplane to form a plurality of interconnects.

Embodiment (t). The method of embodiment (q) to embodiment(s), wherein the backplane is a CMOS backplane.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to the terms first, second, third, etc. may be used herein to describe various elements, and these elements should not be limited by these terms. These terms may be used to distinguish one element from another.

Reference throughout this specification to a layer, region, or substrate as being “on” or extending “onto” another element, means that it may be directly on or extend directly onto the other element or intervening elements may also be present. When an element is referred to as being “directly on” or extending “directly onto” another element, there may be no intervening elements present. Furthermore, when an element is referred to as being “connected” or “coupled” to another element, it may be directly connected or coupled to the other element and/or connected or coupled to the other element via one or more intervening elements. When an element is referred to as being “directly connected” or “directly coupled” to another element, there are no intervening elements present between the element and the other element. It will be understood that these terms are intended to encompass different orientations of the element in addition to any orientation depicted in the figures.

Relative terms such as “below,” “above,” “upper,”, “lower,” “horizontal” or “vertical” may be used herein to describe a relationship of one element, layer, or region to another element, layer, or region as illustrated in the figures. It will be understood that these terms are intended to encompass different orientations of the device in addition to the orientation depicted in the figures.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. In one or more embodiments, the particular features, structures, materials, or characteristics are combined in any suitable manner.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A light-emitting diode (LED) device comprising:
an epitaxial stack comprising a first p-n junction, a second p-n junction, and a third p-n junction on a substrate;
a first electrical contact terminal in contact with the epitaxial stack;
a second electrical contact terminal in contact with the epitaxial stack;
a third electrical contact terminal in contact with the epitaxial stack; and
a fourth electrical contact terminal in contact with the epitaxial stack.

2. The LED device of claim 1, wherein the device is a polychromatic LED chip.

3. The LED device of claim 1, wherein the first electrical contact terminal, the second electrical contact terminal, the third electrical contact terminal, and the fourth electrical contact terminal are on the same side of the device.

4. The LED device of claim 1, wherein the first electrical contact terminal, the second electrical contact terminal, and the third electrical contact terminal are on the same side of the device, and the fourth electrical contact terminal is on an opposing side of the epitaxial stack.

5. The LED device of claim 1, wherein the first electrical contact terminal, the second electrical contact terminal, and the third electrical contact terminal are on the same side of the device, and the fourth electrical contact terminal is on an adjacent side of the epitaxial stack.

6. The LED device of claim 1, wherein the epitaxial stack comprises an n-type layer, a p-type layer, and an active region.

7. The LED device of claim 1, wherein the epitaxial stack comprises a first active region, a second active region, and a third active region.

8. The LED device of claim 7, wherein one or more of the first active region, the second region, and the third active region emits blue light.

9. The LED device of claim 7, wherein one or more of the first active region, the second region, and the third active region emits red light.

10. The LED device of claim 7, wherein one or more of the first active region, the second region, and the third active region emits green light.

11. The LED device of claim 6, wherein one or more of the n-type layer, the active region, and the p-type layer independently comprises one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like.

12. The LED device of claim 11, wherein one or more of the n-type layer, the active region, and the p-type layer independently comprises gallium nitride (GaN).

13. The LED device of claim 1, wherein the device forms a part of a direct-view display.

14. The LED device of claim 1, wherein the device is a micro-LED.

15. An LED direct-view display comprising:
an LED device including epitaxial stack comprising a first p-n junction, a second p-n junction, and a third p-n junction on a substrate, a first electrical contact terminal in contact with the epitaxial stack, a second electrical contact terminal in contact with the epitaxial stack, a third electrical contact terminal in contact with the epitaxial stack, and a fourth electrical contact terminal in contact with the epitaxial stack;
a backplane; and
interconnects connecting the LED device to the backplane.

16. The LED direct-view display of claim 15, wherein the backplane comprises one or more of active electrical circuitry or passive interposer.

17. A method of manufacturing a light-emitting diode (LED) device, the method comprising:
epitaxially growing an epitaxial stack on a substrate, the epitaxial stack comprising a first p-n junction, a second p-n junction, and a third p-n junction;
forming a first electrical contact terminal in contact with the epitaxial stack;
forming a second electrical contact terminal in contact with the epitaxial stack;
forming a third electrical contact terminal in contact with the epitaxial stack; and
forming a fourth electrical contact terminal in contact with the epitaxial stack.

18. The method of claim 17, further comprising removing the epitaxial stack from the substrate.

19. The method of claim 17, further comprising attaching the epitaxial stack and the first electrical contact terminal, the second electrical contact terminal, the third electrical contact terminal and the fourth electrical contact terminal to a backplane to form a plurality of interconnects.

20. The method of claim 19, wherein the backplane is a CMOS backplane.
